(19) United States
(12) Patent Application Publication
(10) Pub. No.: US 2021/0351246 A1
(43) Pub. Date: Nov. 11, 2021

(54) PIXEL LAYOUT STRUCTURE OF OLED, OLED DISPLAY PANEL, AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Hongyang REN, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/051,181

(22) PCT Filed: Jun. 22, 2020
(86) PCT No.: PCT/CN2020/097498

§ 371 Date: Oct. 28, 2020

(30) Foreign Application Priority Data
May 6, 2020 (CN) 202010372915.0

(51) Int. Cl. H01L 27/32; H01L 51/56

(52) U.S. Cl. CPC H01L 27/3218; H01L 51/5056; H01L 51/56; H01L 27/3216

(57) ABSTRACT

The present disclosure provides a pixel layout structure of an organic light emitting diode (OLED), an OLED display panel, and a manufacturing method of the OLED display panel. The OLED display panel includes the pixel layout structure. The pixel layout structure includes pixel unit odd rows and pixel unit even rows arranged in mutual misalignment.

### FIELD OF INVENTION

The present disclosure relates to the field of display technologies, and particularly relates to a pixel layout structure of an organic light emitting diode (OLED), an OLED display panel, and a manufacturing method of the OLED display panel.

### BACKGROUND OF INVENTION

Organic light emitting diodes (OLEDs) display through a self-luminous organic layer. Because no backlight is needed, the OLEDs have faster response times, wider viewing angles, higher contrasts, lighter quality of components, and lower power consumption, and are recognized as the most promising flat panel display technology at present.

At present, the OLEDs are composed of multilayer structures with different functions. A stacking process of materials of the different layers is generally accomplished by vacuum evaporation or inkjet printing (IJP) technology. OLED display screens of mobile phones with high resolution can achieve a resolution close to 600 PPI through a fine metal mask (FMM) and the evaporation technology, but a utilization rate of organic materials of the OLED in this process is extremely low. Meanwhile, large-sized OLED TVs are completed by the inkjet printing technology, and although the utilization rate of materials in this process is much higher than that of the evaporation process, it is limited by specifications of inkjet droplets and accuracy. Thus, the resolution is low and is generally about 230 PPI.

Therefore, it is necessary to find a process technology that not only improves the utilization rate of the OLED materials, but also realizes high resolution of the OLED display screens. Photolithography technology has more than 200 years of development history, mature technical equipment, and a complete process. Materials used in the photolithography technology are inexpensive, such as photoresist, developer, and so on. If an OLED display screen with a high resolution can be made by using the photolithography technology, costs thereof will be greatly reduced.

A pixel layout design of an OLED for making an OLED display screen with a high resolution is proposed in a patent CN106711173A, but the design proposed in the patent is still limited by accuracy of the inkjet printing and the evaporation processes, and ultra-high resolution OLEDs cannot be achieved.

Even though the OLED screen with ultra-high resolution can be achieved, a thickness of a hole transport layer (HTL) needs to be adjusted through vacuum evaporation and FMM to adjust microcavity effects of different colors (RGB), thereby achieving a purpose of balancing colors. However, the evaporation process needs to be separately processed on the hole transport layer (HTL) and a light emitting layer (EML) corresponding to three colors of the RGB, so a manufacturing process of the OLED screen is cumbersome and the production cost is high.

Therefore, a pixel layout design of the OLED in prior art is limited by the accuracy of the inkjet printing and evaporation processes and cannot produce OLED display screens with an ultra-high resolution, while the production costs of a manufacturing method of the OLED display screen with a high-resolution is high.

### Technical Problems

The present disclosure is aimed to provide a pixel layout structure of an organic light emitting diode (OLED), an OLED display panel, and a manufacturing method of the OLED display panel to solve technical problems that a pixel layout design of an OLED in prior art is limited by accuracy of an inkjet printing and an evaporation processes and cannot produce OLED display screens with an ultra-high resolution, and production costs of a manufacturing method of the OLED display screen with a high-resolution is high.

### Technical Solutions

In order to solve the above problems, the present disclosure provides a pixel layout structure of an organic light emitting diode (OLED), including pixel unit odd rows and pixel unit even rows arranged in mutual misalignment; each of the pixel unit odd rows and the pixel unit even rows includes first pixel unit groups, second pixel unit groups, and third pixel unit groups arranged orderly, separately, and alternately on a straight line, each of the first pixel unit groups, the second pixel unit groups, and the third pixel unit groups includes three subpixel units, and the three subpixel units in each of the first pixel unit groups, the second pixel unit groups, and the third pixel unit groups are arranged in a same manner; wherein each of the first pixel unit groups in the pixel unit even rows is disposed between a corresponding one of the second pixel unit groups and a corresponding one of the third pixel unit groups in the pixel unit odd rows, each of the second pixel unit groups in the pixel unit even rows is disposed between a corresponding one of the third pixel unit groups and a corresponding one of the first pixel unit groups in the pixel unit odd rows, and each of the third pixel unit groups in the pixel unit even rows is disposed between a corresponding one of the first pixel unit groups and a corresponding one of the second pixel unit groups in the pixel unit odd rows.

Furthermore, a plurality of RGB pixel units are formed at connection positions of the pixel unit even rows and the pixel unit odd rows, and each of the RGB pixel units includes one of the subpixel units of the first pixel unit groups, one of the subpixel units of the second pixel unit groups, and one of the subpixel units of the third pixel unit groups.

Furthermore, the three subpixel units in each of the first pixel unit groups, the three subpixel units in each of the second pixel unit groups, and the three subpixel units in each of the third pixel unit groups are different, and the subpixel units of the first pixel unit groups, the subpixel units of the second pixel unit groups, and the subpixel units of the third pixel unit groups comprise one group of blue subpixels, red subpixels, and green subpixels, respectively.

Furthermore, an area of each of the blue subpixels is less than an area of each of the red subpixels, and the area of each of the red subpixels is less than an area of each of the green subpixels.

Furthermore, the three subpixel units in each of the first pixel unit groups, the second pixel unit groups, and the third pixel unit groups are arranged in a triangular pattern.

Furthermore, a cross section of each of the three subpixel units in the first pixel unit groups, the second pixel unit groups, and the third pixel unit groups is shaped as any one of a circle, a triangle, a rectangle, and a polygon.

The present disclosure further provides an OLED display panel, including the pixel layout structure of the OLED.

Furthermore, the OLED display panel further includes a first electrode layer, a hole injection layer (HIL), the pixel layout structure of the OLED, an electron transport layer (ETL), an electron injection layer (EIL), and a second electrode layer, which are laminated; specifically, the hole injection layer is disposed on the first electrode layer; the pixel layout structure of the OLED is disposed on the hole injection layer, and each of the subpixel units of the first pixel unit groups, the second pixel unit groups, and the third pixel unit groups in the pixel layout structure of the OLED includes a hole transport layer (HTL) disposed on the hole injection layer and a light emitting layer (EML) disposed on the hole transport layer; the electron transport layer is disposed on the hole injection layer and covers the pixel layout structure of the OLED; the electron injection layer is disposed on the electron transport layer; and the second electrode layer is disposed on the electron injection layer.

Furthermore, the light emitting layer of any one of the three subpixel units in each of the first pixel unit groups, the light emitting layer of any one of the three subpixel units in each of the second pixel unit groups, and the light emitting layer of any one of the three subpixel units in each of the third pixel unit groups are different, and the subpixel units of the first pixel unit groups, the subpixel units of the second pixel unit groups, and the subpixel units of the third pixel unit groups comprise one group of blue subpixels, red subpixels, and green subpixels, respectively; a thickness of the hole transport layer corresponding to each of the blue subpixels is less than a thickness of the hole transport layer corresponding to each of the green subpixels, and the thickness of the hole transport layer corresponding to each of the green subpixels is less than a thickness of the hole transport layer corresponding to each of the red subpixels.

The present disclosure further provides a manufacturing method of an OLED display panel, including followings steps:

manufacturing a first electrode layer and manufacturing a hole injection layer on the first electrode layer by inkjet printing;

coating negative photoresist on the hole injection layer, aligning a first mask upon the negative photoresist, processing exposure and development by using ultraviolet light above the first mask, and cleaning an unexposed part of the negative photoresist by using developing solution to form first etched grooves;

successively manufacturing a hole transport layer and a light emitting layer in each of the first etched grooves by inkjet printing and peeling the negative photoresist to form first pixel unit groups, wherein each of the first pixel unit groups comprises three subpixel units;

coating negative photoresist on the hole injection layer and the first pixel unit groups, aligning a second mask upon the negative photoresist, processing exposure and development by using ultraviolet light above the second mask, and cleaning an unexposed part of the negative photoresist by using developing solution to form second etched grooves;

successively manufacturing a hole transport layer and a light emitting layer in each of the second etched grooves by inkjet printing and peeling the negative photoresist to form second pixel unit groups, wherein each of the second pixel unit groups comprises three subpixel units;

coating negative photoresist on the hole injection layer, the first pixel unit groups, and the second pixel unit groups, aligning a third mask upon the negative photoresist, processing exposure and development by using ultraviolet light above the third mask, and cleaning an unexposed part of the negative photoresist by using developing solution to form third etched grooves;

successively manufacturing a hole transport layer and a light emitting layer in each of the third etched grooves by inkjet printing and peeling the negative photoresist to form third pixel unit groups, wherein each of the third pixel unit groups comprises three subpixel units;

manufacturing an electron transport layer on the hole injection layer and a pixel layout structure of an OLED by inkjet printing;

manufacturing an electron injection layer on the electron transport layer by inkjet printing; and

manufacturing a second electrode layer on the electron injection layer.

### Beneficial Effects

Technical effects of the present disclosure are: a pixel layout structure of an OLED, an OLED display panel, and a manufacturing method of the OLED display panel are provided. The OLED display panel with a high resolution is manufactured by designing the pixel layout structure of the OLED and combining an inkjet printing technology and a photolithography technology. In the manufacturing method, negative photoresists with a blocking effect and etched grooves for manufacturing the subpixel units are formed through a photolithography process, and the subpixel units are manufactured in the etched grooves by inkjet printing, so each layer of organic materials of the OLED display panel can realize a whole surface spraying through the inkjet printing technology without needing to consider a printing accuracy of the inkjet printing. An OLED display screen with an ultra-high resolution of 1800 PPI is manufactured in a simple way and at low production costs by further combining the pixel layout structure of the OLED of the present disclosure.

### DESCRIPTION OF DRAWINGS

FIG. 1 is a schematic view of a pixel layout structure of an OLED according to an embodiment of the present disclosure.

FIG. 2 is a schematic view of an OLED display panel according to a first embodiment of the present disclosure.

FIG. 3 is a schematic view of a first mask, a second mask, and a third mask according to an embodiment of the present disclosure.

FIG. 4 is a schematic view of a second mask according to an embodiment of the present disclosure.

FIG. 5 is a schematic view of a third mask according to an embodiment of the present disclosure.

FIG. 6 is a schematic view showing a process of ultra-violet exposure and development in steps of a manufacturing method of an OLED display panel according to an embodiment of the present disclosure.

FIG. 7 is a schematic view showing a process for manufacturing a hole transport layer and a light emitting layer in steps of the manufacturing method of the OLED display panel according to an embodiment of the present disclosure.

Reference numbers of components in the figures are as followings:

first pixel unit group 1, second pixel unit group 2, third pixel unit group 3,

RGB pixel unit 4, pixel unit odd row 11, pixel unit even row 12,

first mask 21, second mask 22, third mask 23,

first electrode layer 10, hole injection layer 20, pixel layout structure 30 of an OLED,

hole transport layer 31, light emitting layer 32, electron transport layer 40,

hole injection layer 50, second electrode layer 60, negative photoresist 70,

OLED display panel 100.

### DETAILED DESCRIPTION OF EMBODIMENTS

The technical solutions in the embodiments of the present disclosure will be clearly and completely described with reference to the accompanying drawings in the embodiments of the present disclosure. Obviously, the described embodiments are only a part of the embodiments of the present disclosure, but not all the embodiments. Based on the embodiments in the present disclosure, all other embodiments obtained by those skilled in the art without creative work fall into protection scope of the present disclosure.

Following description of each embodiment refers to additional illustrations to illustrate specific embodiments of the present disclosure that can be implemented. Orientational terms mentioned in the present disclosure, such as “upper”, “lower”, “front”, “rear”, “left”, “right”, “inner”, “outer”, “side”, etc., merely refer to directions referring to the attached drawings. Therefore, the orientational terms are used to illustrate and understand the present disclosure, not to limit the present disclosure. In the figures, units with similar structures are indicated by same reference numerals.

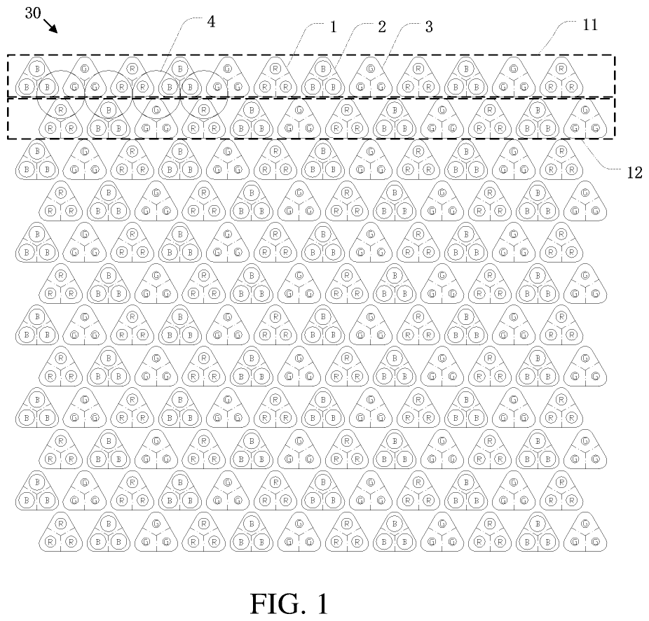

Referring to FIG. 1, an embodiment of the present disclosure provides a pixel layout structure 30 of an organic light emitting diode (OLED), which includes pixel unit odd rows 11 and pixel unit even rows 12 arranged in mutual misalignment. Each of the pixel unit odd rows 11 and the pixel unit even rows 12 includes first pixel unit groups 1, second pixel unit groups 2, and third pixel unit groups 3 arranged orderly, separately, and alternately on a straight line. Each of the first pixel unit groups 1, the second pixel unit groups 2, and the third pixel unit groups 3 includes three subpixel units, and the three subpixel units in each of the first pixel unit groups 1, the second pixel unit groups 2, and the third pixel unit groups 3 are arranged in a same manner. Wherein each of the first pixel unit groups 1 in the pixel unit even rows 12 is disposed between a corresponding one of the second pixel unit groups 2 and a corresponding one of the third pixel unit groups 3 in the pixel unit odd rows 11, each of the second pixel unit groups 2 in the pixel unit even rows 12 is disposed between a corresponding one of the third pixel unit groups 3 and a corresponding one of the first pixel unit groups 1 in the pixel unit odd rows 11, and each of the third pixel unit groups 3 in the pixel unit even rows 12 is disposed between a corresponding one of the first pixel unit groups 1 and a corresponding one of the second pixel unit groups 2 in the pixel unit odd rows 11.

As shown in FIG. 1, a plurality of RGB pixel units 4 are formed at connection positions of the pixel unit even rows 12 and the pixel unit odd rows 11. Circular frames (with letters) defined by solid lines indicate that the pixel layout structure 30 of the OLED is divided into the plurality of RGB pixel units 4, which are RGB pixels defined by a pixel definition layer (PDL) on a substrate of the OLED. Each of the RGB pixel units 4 includes one of the subpixel units of the first pixel unit groups 1, one of the subpixel units of the second pixel unit groups 2, and one of the subpixel units of the third pixel unit groups 3, that is, including three subpixels of R, G, and B. “Y” defined by dotted lines merely serves to distinguish the three subpixel units in one of the pixel unit groups, and there is no actual entity. Each of the circular frames containing the three subpixels of R, G, and B merely represents one imaging pixel, and there is no actual entity, that is, referring to an area where a light emitting layer is located.

As shown in FIG. 1, each of the first pixel unit groups 1, the second pixel unit groups 2, and the third pixel unit groups 3 includes three subpixel units, and each group of the three subpixel units are arranged in a same manner of 3 IN 1. Each of the subpixel units can achieve a resolution of 600 PPI through being manufactured by photoetching a mask, thereby preventing the resolution from being limited to about 230 PPI as being manufactured by inkjet printing. Thus, each of the first pixel unit groups 1, the second pixel unit groups 2, and the third pixel unit groups 3 can achieve a resolution of 1800 PPI, so that a resolution of a display panel having the pixel layout structure 30 of the OLED can be further increased to 1800 PPI.

In the embodiment, the three subpixel units in each of the first pixel unit groups 1, the three subpixel units in each of the second pixel unit groups 2, and the three subpixel units in each of the third pixel unit groups 3 are different from each other, and the subpixel units of the first pixel unit groups 1, the subpixel units of the second pixel unit groups 2, and the subpixel units of the third pixel unit groups 3 refer to one group of blue subpixels (B), red subpixels (R), and green subpixels (G), respectively. In FIG. 1, the blue subpixel (B), the red subpixel (R), and the green subpixel (G) are respectively represented by the circular frames including three subpixels of B, R, and G.

In the embodiment, an area of each of the blue subpixels is less than an area of each of the red subpixels, and the area of each of the red subpixels is less than an area of each of the green subpixels. This arrangement can make an emission color of the blue subpixel (B), the red subpixel (R), and the green subpixel (G) uniform.

In the embodiment, the three subpixel units in each of the first pixel unit groups 1, the second pixel unit groups 2, and the third pixel unit groups 3 are arranged in a triangular pattern. However, an arrangement shape of the three subpixel units is not limited to triangular, as long as the three subpixel units of a same color are included in one of the first pixel unit groups 1, the second pixel unit groups 2, and the third pixel unit groups 3.

In the embodiment, each of the three subpixel units in the first pixel unit groups 1, the second pixel unit groups 2, and the third pixel unit groups 3 are shaped as a column. A cross section of each of the three subpixel units in the first pixel unit groups 1, the second pixel unit groups 2, and the third pixel unit groups 3 is shaped as any one of a circle, a triangle, a rectangle, and a polygon.

Referring to FIG. 2, the present disclosure further provides an OLED display panel 100, including the pixel layout structure 30 of the OLED.

The OLED display panel 100 of the present disclosure can be applied to various occasions, and can be combined with various devices and structures. The OLED display panel 100 can be either a mobile terminal (mobile phone or smart wearable) or a fixed terminal (PC), and can also be other devices with display functions, such as a tablet computer, a television, a display window, etc. It should be understood that, in order to realize functions, the OLED display panel 100 of the present disclosure is provided with other devices and structures not shown in this specification.

Referring to FIG. 2, in the embodiment, the OLED display panel 100 further includes a first electrode layer 10, a hole injection layer (HIL) 20, the pixel layout structure 30 of the OLED, an electron transport layer (ETL) 40, an electron injection layer (EIL) 50, and a second electrode layer 60, which are laminated.

Specifically, the first electrode layer 10 is made of indium tin oxide (ITO) and refers to an anode. The hole injection layer 20 is disposed on the first electrode layer 10. The pixel layout structure 30 of the OLED is disposed on the hole injection layer 20, and each of the subpixel units of the first pixel unit groups 1, the second pixel unit groups 2, and the third pixel unit groups 3 in the pixel layout structure 30 of the OLED includes a hole transport layer (HTL) 31 disposed on the hole injection layer 20 and a light emitting layer (EML) 32 disposed on the hole transport layer 31. Specifically, the hole transport layers 31 include hole transport unit odd rows and hole transport unit even rows arranged in mutual misalignment, each of the hole transport unit odd rows and the hole transport unit even rows includes first hole transport unit groups, second hole transport unit groups, and third hole transport unit groups arranged orderly, separately, and alternately on a straight line, each of the first hole transport unit groups, the second hole transport unit groups, and the third hole transport unit groups includes three sub-hole transport units, and the three sub-hole transport units in each of the first hole transport unit groups, the second hole transport unit groups, and the third hole transport unit groups are arranged in a same manner. The light emitting layer 32 includes first light emitting unit groups, second light emitting unit groups, and third light emitting unit groups corresponding to the first hole transport unit groups, the second hole transport unit groups, and the third hole transport unit groups, each of the first light emitting unit groups, the second light emitting unit groups, and the third light emitting unit groups includes three sub-light emitting units, and the three sub-light emitting units in each of the first light emitting unit groups, the three sub-light emitting units in each of the second light emitting unit groups, and the three sub-light emitting units in each of the third light emitting unit groups are respectively disposed to be corresponding to the three sub-hole transport units in each of the first hole transport unit groups, the three sub-hole transport units in each of the second hole transport unit groups, and the three sub-hole transport units in each of the third hole transport unit groups. The electron transport layer 40 is disposed on the hole injection layer 20 and covers the pixel layout structure 30 of the OLED. The electron injection layer 50 is disposed on the electron transport layer 40. And the second electrode layer 60 is disposed on the electron injection layer 50 and refers to a cathode.

In the embodiment, the light emitting layer 32 of any one of the three subpixel units in each of the first pixel unit groups 1, the light emitting layer 32 of any one of the three subpixel units in each of the second pixel unit groups 2 , and the light emitting layer 32 of any one of the three subpixel units in each of the third pixel unit groups 3 are different from each other, and the subpixel units of the first pixel unit groups 1, the subpixel units of the second pixel unit groups 2, and the subpixel units of the third pixel unit groups 3 include one group of blue subpixels, red subpixels, and green subpixels, respectively. In the three subpixel units of each first pixel unit group 1, the three subpixel units of each second pixel unit group 2, and the three subpixel units of each third pixel unit group 3, the light emitting layers 32 have a same thickness, and the hole transport layers 31 have different thicknesses. Specifically, a thickness of the hole transport layer 31 corresponding to each of the blue subpixels is less than a thickness of the hole transport layer 31 corresponding to each of the green subpixels, and the thickness of the hole transport layer 31 corresponding to each of the green subpixels is less than a thickness of the hole transport layer 31 corresponding to each of the red subpixels. This arrangement can make an emission color of the blue subpixel (B), the red subpixel (R), and the green subpixel (G) uniform.

Referring from FIG. 2 to FIG. 7, the present disclosure further provides a manufacturing method of the OLED display panel 100, including steps of S1-S10.

Step S1, manufacturing a first electrode layer 10 and manufacturing a hole injection layer on the first electrode layer by inkjet printing, wherein the first electrode layer 10 is made of indium tin oxide (ITO) and refers to an anode.

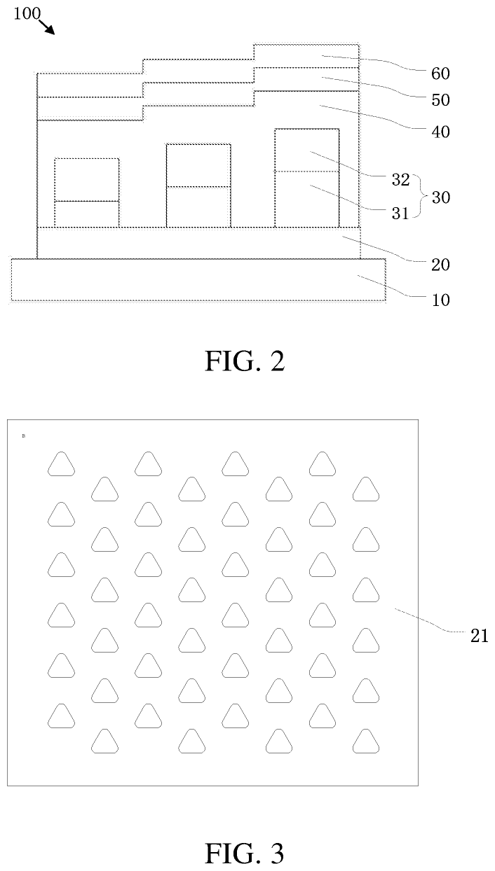

Step S2, coating a negative photoresist 70 on the hole injection layer 20, aligning a first mask 21 upon the negative photoresist 70, processing exposure and development by using ultraviolet light above the first mask 21, and cleaning an unexposed part of the negative photoresist 70 by using developing solution to form first etched grooves, wherein a structure of the first mask 21 is as shown in FIG. 3.

Step S3, successively manufacturing a hole transport layer 31 and a light emitting layer 32 in each of the first etched grooves by inkjet printing, and peeling the negative photoresist 70 to form first pixel unit groups 1, wherein each of the first pixel unit groups 1 includes three subpixel units.

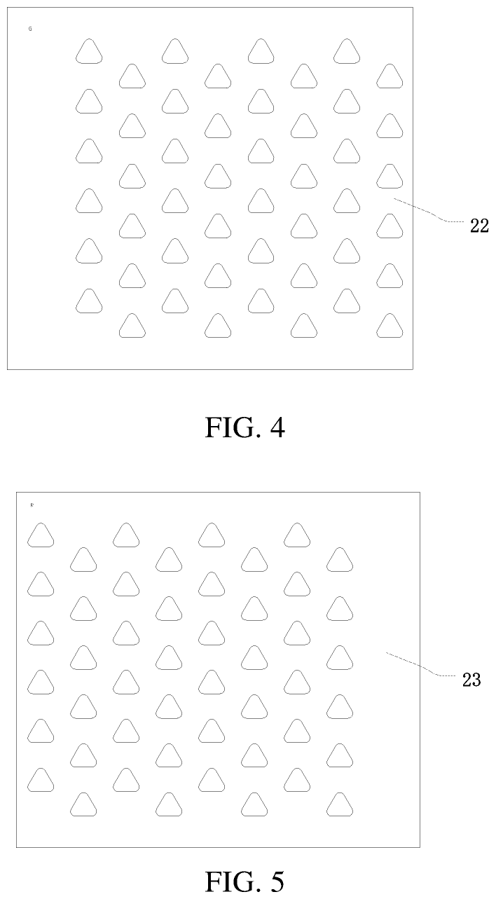

Step S4, coating a negative photoresist 70 on the hole injection layer 20 and the first pixel unit groups 1, aligning a second mask 22 upon the negative photoresist 70, processing exposure and development by using ultraviolet light above the second mask 22, and cleaning an unexposed part of the negative photoresist 70 by using developing solution to form second etched grooves, wherein a structure of the second mask 22 is shown in FIG. 4.

Step S5, successively manufacturing a hole transport layer 31 and a light emitting layer 32 in each of the second etched grooves by inkjet printing, and peeling the negative photoresist 70 to form second pixel unit groups 2, wherein each of the second pixel unit groups 2 includes three subpixel units.

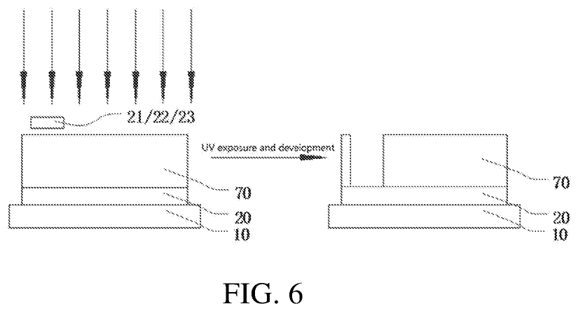

Step S6, coating a negative photoresist 70 on the hole injection layer 20, the first pixel unit groups 1, and the second pixel unit groups 2, aligning a third mask 23 upon the negative photoresist 70, processing exposure and development by using ultraviolet light above the third mask 23, and cleaning an unexposed part of the negative photoresist 70 by using developing solution to form third etched grooves, wherein a structure of the third mask 23 is shown in FIG. 5.

Wherein, a process of the exposure and development by using ultraviolet light in steps S2, S4, and S6 are as shown in FIG. 6. The negative photoresist 70 and the supporting developer and stripping solution used in steps S2-S6 are compatible with organic materials and will not damage properties of the organic materials. The negative photoresist 70 has a photosensitive component, the photosensitive component contains a halogen solvent, a photoacid generator compound, a monomer containing at least one fluorine group, and a copolymer containing at least one acid-cleavable ester group-containing monomer. Images/patterns on the masks are then transferred to the negative photoresist layers 70 with UV exposure, thereby forming the first etched grooves, the second etched grooves, and the third etched grooves. Each etched groove is made by photoresist masks, so each etched groove can easily achieve a resolution of 600 PPI. Furthermore, the subpixel units are manufactured by an inkjet printing method in the etched grooves, so that each layer of the organic materials of the OLED display panel 100 can be sprayed on an entire surface by the inkjet printing technology, without needing to consider a printing accuracy of the inkjet printing. Then, the pixel layout structure 30 of the OLED of the present disclosure is combined to realize production of an OLED display screen with an ultra-high resolution of 1800 PPI. According to shapes of the first etched grooves, the second etched grooves, and the third etched grooves of the embodiment, corresponding photoresist masks are designed and matched. The photoresist masks corresponding to the blue subpixels, the red subpixels, and the green subpixels are the first mask 21, the second mask 22, and the third mask 23 as shown in FIGS. 3, 4, and 5, respectively. Since areas and shapes of unexposed areas corresponding to the subpixels with three colors can be designed to be the same, that is, areas and shapes of the first etched grooves, the second etched grooves, and the third etched grooves are same, it is only necessary to change an arrangement of the corresponding unexposed areas, so design and production costs of the photoresist mask can be effectively reduced.

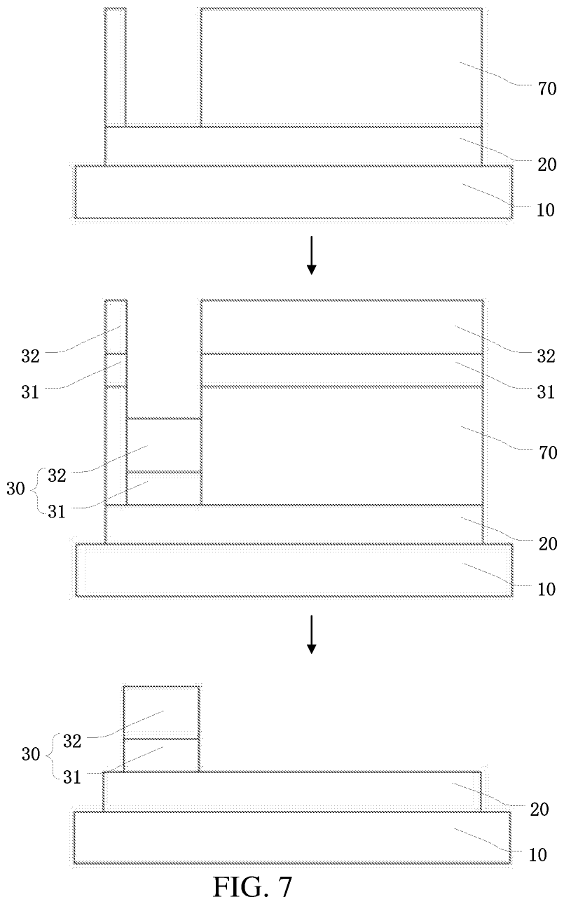

Step S7, successively manufacturing a hole transport layer 31 and a light emitting layer 32 in each of the third etched grooves by inkjet printing, and peeling the negative photoresist 70 to form third pixel unit groups 3, wherein each of the third pixel unit groups 3 includes three subpixel units.

Wherein, a process of manufacturing the hole transport layer 31 and the light emitting layer 32 in steps S3, S5, and S7 to form the first pixel unit groups 1, the second pixel unit groups 2, and the third pixel unit groups 3 are as shown in FIG. 7. The three subpixel units of the first pixel unit groups 1, the second pixel unit groups 2, and the third pixel unit groups 3 formed in steps S3, S5, and S7 are arranged in a same manner. The first pixel unit groups 1, the second pixel unit groups 2, and the third pixel unit groups 3 are sequentially arranged orderly, separately, and alternately on a straight line to form pixel unit odd rows 11 and pixel unit even rows 12 arranged in mutual misalignment. Each of the first pixel unit groups 1 in the pixel unit even rows 12 is correspondingly disposed between one of the second pixel unit groups 2 and one of the third pixel unit groups 3 in the pixel unit odd rows 11, each of the second pixel unit groups 2 in the pixel unit even rows 12 is correspondingly disposed between one of the third pixel unit groups 3 and one of the first pixel unit groups 1 in the pixel unit odd rows 11, and each of the third pixel unit groups 3 in the pixel unit even rows 12 is correspondingly disposed between one of the first pixel unit groups 1 and one of the second pixel unit groups 2 in the pixel unit odd rows 11.

Step S8, manufacturing an electron transport layer 40 on the hole injection layer 20 and the pixel layout structure 30 of the OLED by inkjet printing.

Step S9, manufacturing an electron injection layer 50 on the electron transport layer 40 by inkjet printing;

Step S10, manufacturing a second electrode layer 60 on the electron injection layer 50 through an evaporation process. The second electrode layer 60 refers to a cathode.

A completed OLED display panel 100 is shown in FIG. 2, so that a plurality of RGB pixel units 4 are formed at the connection positions of the pixel unit even rows 12 and the pixel unit odd rows 11. Circular frames (with letters) defined by solid lines indicate that the pixel layout structure 30 of the OLED is divided into the plurality of RGB pixel units 4, which are RGB pixels defined by a pixel definition layer (PDL) on a substrate of the OLED. Each of the RGB pixel units 4 includes one of the subpixel units of the first pixel unit groups 1, one of the subpixel units of the second pixel unit groups 2, and one of the subpixel units of the third pixel unit groups 3, that is, including three subpixels of R, G, and B. “Y” defined by dotted lines merely serves to distinguish the three subpixel units in one of the pixel unit groups, and there is no actual entity. Each of the circular frames containing the three subpixels of R, G, and B merely represents one imaging pixel, and there is no actual entity, that is, referring to an area where a light emitting layer is located.

Wherein, each of the first pixel unit groups 1, the second pixel unit groups 2, and the third pixel unit groups 3 includes three subpixel units, and each group of the three subpixel units are arranged in a same manner of 3 IN 1. Each of the subpixel units can achieve a resolution of 600 PPI through being manufactured by photoetching a mask, thereby preventing the resolution from being limited to about 230 PPI as being manufactured by inkjet printing. Thus, each of the first pixel unit groups 1, the second pixel unit groups 2, and the third pixel unit groups 3 can achieve a resolution of 1800 PPI, so that a resolution of a display panel having the pixel layout structure 30 of the OLED can be further increased to 1800 PPI.

In the manufacturing method of the OLED display panel 100 provided by the present disclosure, photolithography technology is used to etch negative photoresists 70 to form etched grooves. Each etched groove is made by photoresist masks, so each etched groove can easily achieve a resolution of 600 PPI. Furthermore, the subpixel units are manufactured by an inkjet printing method in the etched grooves, so that each layer of the organic materials of the OLED display panel 100 can be sprayed on an entire surface by the inkjet printing technology, without considering a printing accuracy of the inkjet printing. Then, the pixel layout structure 30 of the OLED of the present disclosure is combined to realize production of an OLED display screen with an ultra-high resolution of 1800 PPI. Since inkjet printing refers to a full-surface spraying, the printing accuracy does not need to be considered, so the manufacturing method is simple and the costs is low.

Technical effects of the present disclosure are: a pixel layout structure of an OLED, an OLED display panel, and a manufacturing method of the OLED display panel are provided. The OLED display panel with a high resolution is manufactured by designing the pixel layout structure of the OLED and combining an inkjet printing technology and a photolithography technology. In the manufacturing method, negative photoresists 70 with a blocking effect and etched grooves for manufacturing the subpixel units are formed through a photolithography process, and the subpixel units are manufactured in the etched grooves by inkjet printing, so each layer of organic materials of the OLED display panel can realize a whole surface spraying through the inkjet printing technology without needing to consider a printing accuracy of the inkjet printing. An OLED display screen with an ultra-high resolution of 1800 PPI is manufactured in a simple way and at low production costs by further combining the pixel layout structure of the OLED of the present disclosure.

The above is only a preferred embodiment of the present invention, it should be noted that for those of ordinary skill in the art, without departing from the principles of the present disclosure, a number of improvements and retouches can be made, and these improvements and retouches should also be regarded as a protection scope of the present disclosure.

1. A pixel layout structure of an organic light emitting diode (OLED), comprising pixel unit odd rows and pixel unit even rows arranged in mutual misalignment;
wherein each of the pixel unit odd rows and the pixel unit even rows comprises first pixel unit groups, second pixel unit groups, and third pixel unit groups arranged orderly, separately, and alternately on a straight line, each of the first pixel unit groups, the second pixel unit groups, and the third pixel unit groups comprises three subpixel units, and the three subpixel units in each of the first pixel unit groups, the second pixel unit groups, and the third pixel unit groups are arranged in a same manner; and
wherein each of the first pixel unit groups in the pixel unit even rows is disposed between a corresponding one of the second pixel unit groups and a corresponding one of the third pixel unit groups in the pixel unit odd rows, each of the second pixel unit groups in the pixel unit even rows is disposed between a corresponding one of the third pixel unit groups and a corresponding one of the first pixel unit groups in the pixel unit odd rows, and each of the third pixel unit groups in the pixel unit even rows is disposed between a corresponding one of the first pixel unit groups and a corresponding one of the second pixel unit groups in the pixel unit odd rows.

2. The pixel layout structure of the OLED in claim 1, wherein a plurality of RGB pixel units are formed at connection positions of the pixel unit even rows and the pixel unit odd rows, and each of the RGB pixel units comprises one of the subpixel units of the first pixel unit groups, one of the subpixel units of the second pixel unit groups, and one of the subpixel units of the third pixel unit groups.

3. The pixel layout structure of the OLED in claim 1, wherein the three subpixel units in each of the first pixel unit groups, the three subpixel units in each of the second pixel unit groups, and the three subpixel units in each of the third pixel unit groups are different, and the subpixel units of the first pixel unit groups, the subpixel units of the second pixel unit groups, and the subpixel units of the third pixel unit groups comprise one group of blue subpixels, red subpixels, and green subpixels, respectively.

4. The pixel layout structure of the OLED in claim 3, wherein an area of each of the blue subpixels is less than an area of each of the red subpixels, and the area of each of the red subpixels is less than an area of each of the green subpixels.

5. The pixel layout structure of the OLED in claim 1, wherein the three subpixel units in each of the first pixel unit groups, the second pixel unit groups, and the third pixel unit groups are arranged in a triangular pattern.

6. The pixel layout structure of the OLED in claim 1, wherein a cross section of each of the three subpixel units in the first pixel unit groups, the second pixel unit groups, and the third pixel unit groups is shaped as any one of a circle, a triangle, a rectangle, and a polygon.

7. An organic light emitting diode (OLED) display panel, comprising the pixel layout structure of the OLED in claim 1.

8. The OLED display panel in claim 7, further comprising:
a first electrode layer;
a hole injection layer disposed on the first electrode layer;
the pixel layout structure of the OLED disposed on the hole injection layer, wherein each of the subpixel units of the first pixel unit groups, the second pixel unit groups, and the third pixel unit groups in the pixel layout structure of the OLED comprises a hole transport layer disposed on the hole injection layer and a light emitting layer disposed on the hole transport layer;
an electron transport layer disposed on the hole injection layer and covering the pixel layout structure of the OLED;
an electron injection layer disposed on the electron transport layer; and
a second electrode layer disposed on the electron injection layer.

9. The OLED display panel in claim 8, wherein
the light emitting layer of any one of the three subpixel units in each of the first pixel unit groups, the light emitting layer of any one of the three subpixel units in each of the second pixel unit groups, and the light emitting layer of any one of the three subpixel units in each of the third pixel unit groups are different, and the subpixel units of the first pixel unit groups, the subpixel units of the second pixel unit groups, and the subpixel units of the third pixel unit groups comprise one group of blue subpixels, red subpixels, and green subpixels, respectively;
a thickness of the hole transport layer corresponding to each of the blue subpixels is less than a thickness of the hole transport layer corresponding to each of the green subpixels, and the thickness of the hole transport layer corresponding to each of the green subpixels is less than a thickness of the hole transport layer corresponding to each of the red subpixels.

10. A manufacturing method of an organic light emitting diode (OLED) display panel, comprising followings steps:
manufacturing a first electrode layer and manufacturing a hole injection layer on the first electrode layer by inkjet printing;
coating a first negative photoresist on the hole injection layer, aligning a first mask upon the first negative photoresist, processing exposure and development by using ultraviolet light above the first mask, and cleaning an unexposed part of the first negative photoresist by using developing solution to form first etched grooves;
successively manufacturing a hole transport layer and a light emitting layer in each of the first etched grooves by inkjet printing and peeling the first negative photoresist to form first pixel unit groups, wherein each of the first pixel unit groups comprises three subpixel units;
coating a second negative photoresist on the hole injection layer and the first pixel unit groups, aligning a second mask upon the second negative photoresist, processing exposure and development by using ultraviolet light above the second mask, and cleaning an unexposed part of the second negative photoresist by using developing solution to form second etched grooves;
successively manufacturing a hole transport layer and a light emitting layer in each of the second etched grooves by inkjet printing and peeling the second negative photoresist to form second pixel unit groups, wherein each of the second pixel unit groups comprises three subpixel units;
coating a third negative photoresist on the hole injection layer, the first pixel unit groups, and the second pixel unit groups, aligning a third mask upon the third negative photoresist, processing exposure and development by using ultraviolet light above the third mask, and cleaning an unexposed part of the third negative photoresist by using developing solution to form third etched grooves;
successively manufacturing a hole transport layer and a light emitting layer in each of the third etched grooves by inkjet printing and peeling the third negative photoresist to form third pixel unit groups, wherein each of the third pixel unit groups comprises three subpixel units, wherein the first pixel unit groups, the second pixel unit groups, and the third pixel unit groups together form a pixel layout structure of an organic light emitting diode (OLED);
manufacturing an electron transport layer on the hole injection layer and the pixel layout structure of the OLED by inkjet printing;
manufacturing an electron injection layer on the electron transport layer by inkjet printing; and
manufacturing a second electrode layer on the electron injection layer.
